(19) United States
(12) Patent Application Publication
(10) Pub. No.: US 2008/0160768 A1
(43) Pub. Date: Jul. 3, 2008

(54) METHOD OF MANUFACTURING GATE DIELECTRIC LAYER

(75) Inventors: Chih-Jung Ni, Hsinchu (TW); Ching-Jen Han, Taichung City (TW); Wen-Shun Lo, Hsinchu County (TW)

Correspondence Address: J C PATENTS, INC., 4 VENTURE, SUITE 250, IRVINE, CA, 92618, US

(73) Assignee: WINBOND ELECTRONICS CORP., Hsinchu (TW)

(21) Appl. No.: 11/747,799

(22) Filed: May 11, 2007

(30) Foreign Application Priority Data
Dec. 28, 2006 (TW) 95149456

(51) Int. Cl. H01L 21/311

(52) U.S. Cl. 438/703; 257/E21.249

(57) ABSTRACT

A method of manufacturing a gate dielectric layer is described. First, a substrate including a high voltage device region and a low voltage device region is provided. Plural isolation structures are formed in the substrate and protrude from the substrate. A high voltage gate dielectric layer is then formed on the substrate, and a passivation layer is formed on the high voltage gate dielectric layer in the high voltage device region. Next, a dry etching step is performed to remove a portion of the high voltage gate dielectric layer in the low voltage device region. Thereafter, a wet etching step is performed to remove the remaining high voltage gate dielectric layer in the low voltage device region. The passivation layer is then removed and a low voltage gate dielectric layer is formed on the substrate in the low voltage device region.

### CROSS-REFERENCE TO RELATED APPLICATION

This application claims the priority benefit of Taiwan application serial no. 95149456, filed Dec. 28, 2006. All disclosure of the Taiwan application is incorporated herein by reference.

### BACKGROUND OF THE INVENTION

1. Field of the Invention

The present invention relates to a method for manufacturing a semiconductor device. More particularly, the present invention relates to a method for manufacturing a gate dielectric layer.

2. Description of Related Art

With the rapid development of the integrated circuit fabrication technologies, the production and the design of highly efficient, highly integrated, low cost, light and compact electronic devices have been pursued by numerous types of electronic products.

Integrating high voltage devices with low voltage devices on the same chip is one of the methods which meet the above requirements. For example, the low voltage devices may be employed for fabricating control circuits, and the high voltage devices may be used for fabricating electrically programmable read-only-memories (EPROMs), flash memories or driving circuits of liquid crystal displays.

However, in order to withstand a high breakdown voltage, a thickness of a gate oxide layer in the high voltage device is frequently required to exceed 200 angstrom. Said thickness is considerably greater than the thickness of the gate oxide layer in the low voltage device. With this particular requirement, various problems emerge in the process of integrating the high voltage devices with the low voltage devices.

FIGS. 1A through 1C are cross-sectional views depicting a process of manufacturing a conventional gate oxide layer. Referring to FIG. 1A, a substrate 100 includes a high voltage device region 102 and a low voltage device region 104. An isolation structure 110 is disposed in the substrate 100. A high voltage gate oxide layer 120 is disposed on the substrate 100, and a photoresist layer 130 is disposed on the high voltage gate oxide layer 120 in the high voltage device region 102.

Next, referring to FIG. 1B, the high voltage gate oxide layer 120 in the low voltage device region 104 is removed by performing a wet etching step, such that the substrate 100 is exposed. An etchant employed in the wet etching step etches the isolation structure 110, such that a divot 115 is formed at a boundary between the isolation structure 110 and the substrate 100.

Thereafter, referring to FIG. 1C, the photoresist layer 130 is removed, and a low voltage gate oxide layer 140 is formed on the substrate 100 by performing a thermal oxidation process. The divot 115 formed at a corner portion of the isolation structure 110 affects an oxidation rate of the silicon substrate 100, such that the low voltage gate oxide layer 140 formed at the boundary between the isolation structure 110 and the substrate 100 is thinner. Such non-uniformity in the thickness of the gate oxide layer 140 is the so-called gate oxide thinning phenomenon which compromises the reliability of the gate oxide layer and brings about electrical problems in the devices, such as charge-to-breakdown, voltage breakdown, threshold voltage shift, and so on.

### SUMMARY OF THE INVENTION

In view of the foregoing, the present invention provides a method of manufacturing a gate dielectric layer. The method is capable of suppressing side etching of an isolation structure and preventing a low voltage gate dielectric layer from thinning.

The present invention provides a method of manufacturing a gate dielectric layer, including firstly providing a substrate having a high voltage device region and a low voltage device region. A plurality of isolation structures is formed in the substrate and protrudes therefrom. A high voltage gate dielectric layer is then formed on the substrate, and a passivation layer is formed on the high voltage gate dielectric layer in the high voltage device region. Next, a dry etching step is performed to remove a portion of the high voltage gate dielectric layer in the low voltage device region. Thereafter, a wet etching step is performed to remove the remaining high voltage gate dielectric layer in the low voltage device region. The passivation layer is then removed and a low voltage dielectric layer is formed on the substrate in the low voltage device region.

According to one embodiment of the present invention, in the method of manufacturing the gate dielectric layer, a boundary between the isolation structure and a surface of the substrate is located higher than a corner portion of the substrate.

In said method of manufacturing the gate dielectric layer, the dry etching step is performed prior to the wet etching step. With a reduction of the etchant supplied for the wet etching step, the formation of divots resulting from the side etching of the isolation structure can be restricted. Thereby, the thinning phenomenon of the subsequently formed low voltage gate dielectric layer is also prevented, and the reliability of the low voltage gate dielectric layer can be further enhanced.

In order to make the above and other objects, features and advantages of the present invention more comprehensible, several embodiments accompanied with figures are described in detail below.

### BRIEF DESCRIPTION OF THE DRAWINGS

FIGS. 1A through 1C are cross-sectional views depicting a process of manufacturing a conventional gate oxide layer.

FIGS. 2A through 2D are cross-sectional views depicting a process of manufacturing a gate dielectric layer according to one embodiment of the present invention.

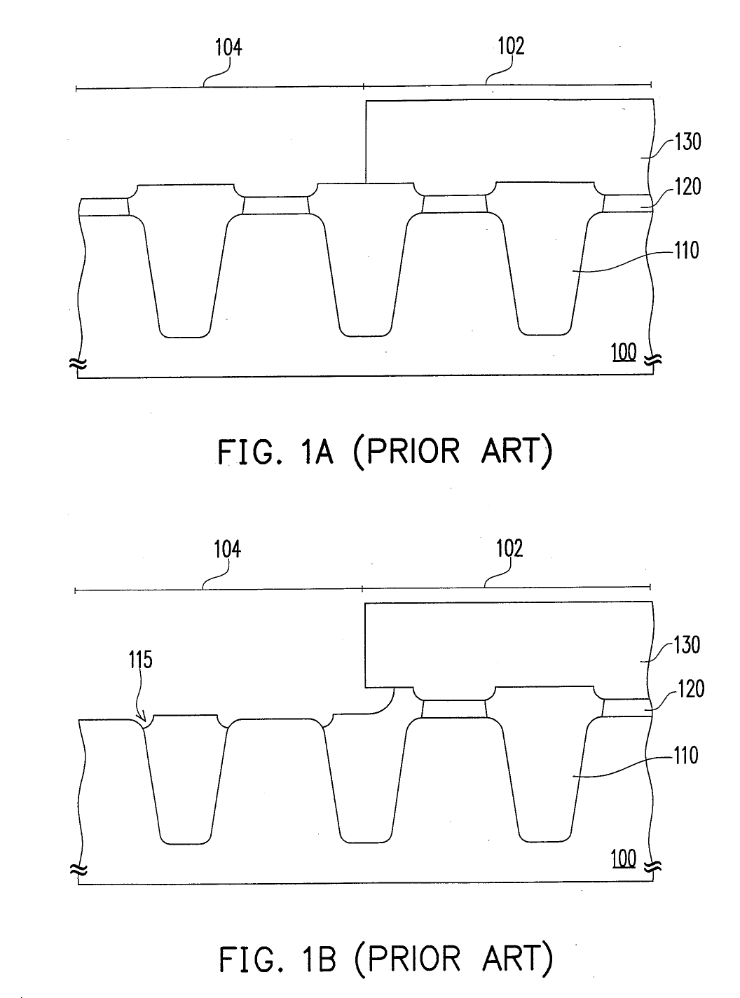

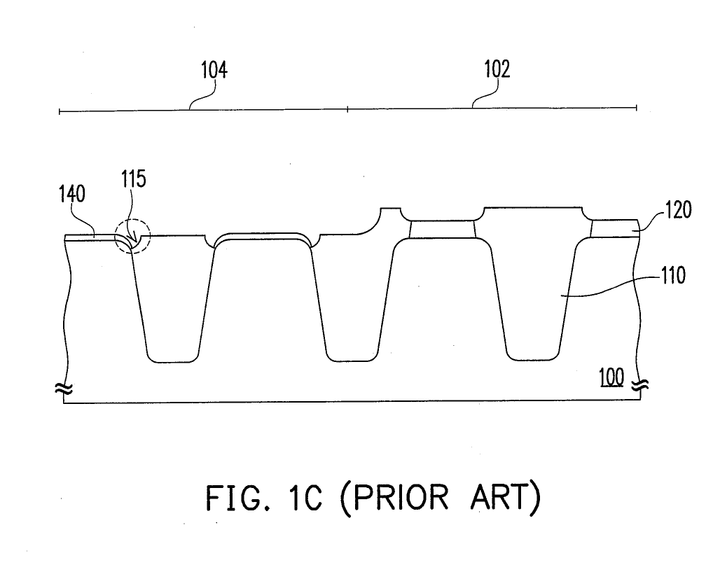

### DESCRIPTION OF EMBODIMENTS

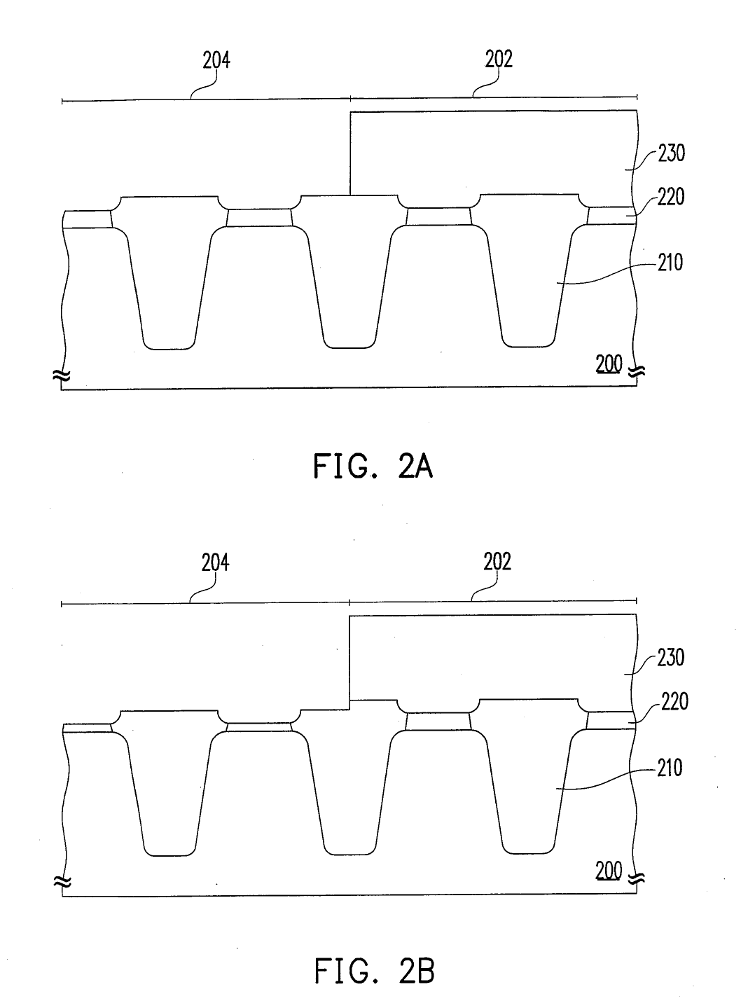

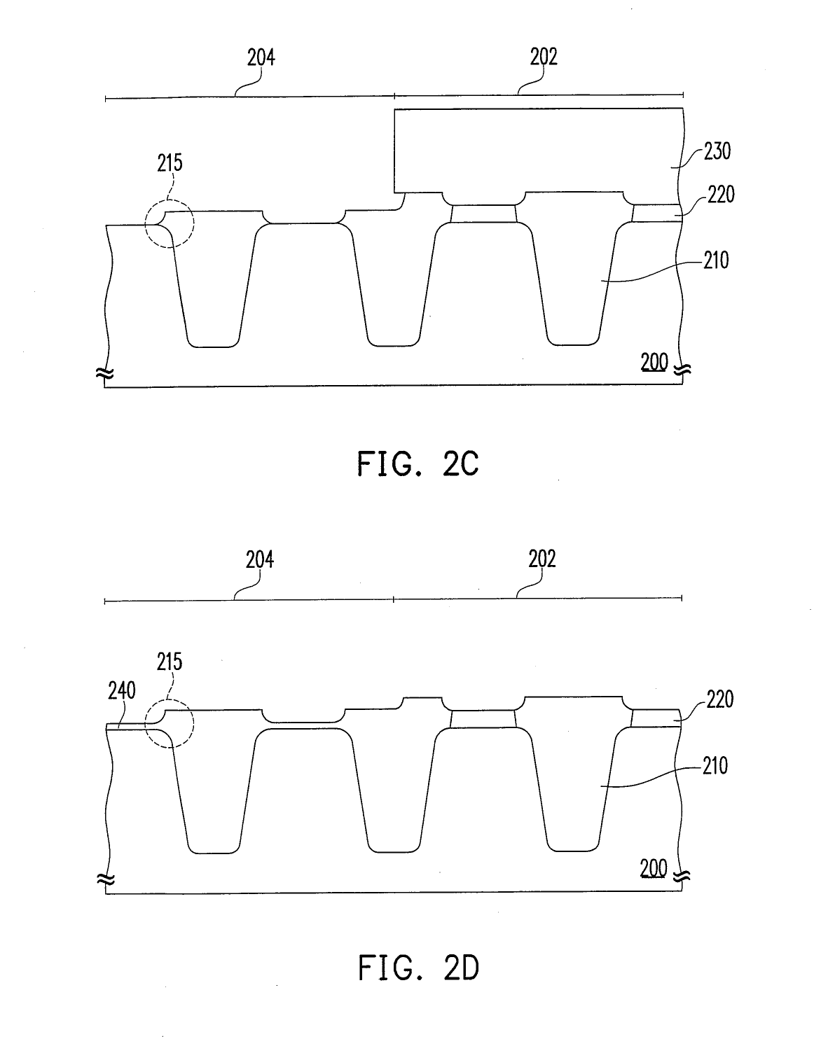

FIGS. 2A through 2D are cross-sectional views depicting a method of manufacturing a gate dielectric layer according to one embodiment of the present invention.

Referring to FIG. 2A, the method disclosed in the present invention for preventing the gate dielectric layer from thinning includes firstly providing a substrate 200. The substrate 200 is, for example, a semiconductor substrate such as a silicon substrate. At least a high voltage device region 202 and a low voltage device region 204 are included in the substrate 200. A plurality of isolation structures 210 is formed in the substrate 200. The isolation structures 210 protrude from the substrate 200. In other words, top surfaces of the isolation structures 210 are higher than the surface of the substrate 200. The isolation structures 210 are, for example, shallow trench isolation (STI) structures, and the material thereof is, for example, silicon oxide. In addition, the method of forming the isolation structures 210 includes, for example, performing an etching process and then performing a high density plasma chemical vapor deposition (HDP-CVD) process, which are well known to those skilled in the art, and thus is not described herein.

Thereafter, a high voltage gate dielectric layer 220 is formed on the substrate 200. The material of the high voltage gate dielectric layer 220 is, for example, silicon oxide, and the method of forming the same includes, for example, performing a thermal oxidation process or a chemical vapor deposition (CVD) process. According to one embodiment, the high voltage gate dielectric layer 220 has a thickness in a range from 200 to 500 angstrom, preferably from 250 to 450 angstrom, for the high voltage gate dielectric layer 220 is required to withstand a high voltage.

Thereafter, a passivation layer 230 is formed on the high voltage gate dielectric layer 220 in the high voltage device region 202. The passivation layer 230 is, for example, a patterned photoresist layer, and the method of forming the same includes, for example, performing a spin coating process (not shown) to form a photoresist layer on the substrate 200 and developing the photoresist layer after exposing the same, such that the patterned photoresist layer is formed. The passivation layer 230 can surely be mask layers made up of other materials, such as silicon nitride and silicon carbide.

Next, referring to FIG. 2B, a dry etching step is performed to remove a portion of the high voltage gate dielectric layer 202 in the low voltage device region 204. The dry etching step includes performing a plasma etching process or a reactive ion etching process, for example. To avoid plasma damage to the substrate 200, the dry etching step is, for example, a low power dry etching step. The power consumed is, for example, in the range of 50˜200 watt, preferably in the range of 80˜120 watt. According to one embodiment, the reactive ion etching process with low power consumption is employed, for example.

For fear of generating irremovable polymers in excess and of affecting a subsequent wet etching step, the etching gas employed in the dry etching step is preferably the polymer-less etching gas. And the etching gas is, for example, the gas employed to etch silicon oxide, including carbon tetrafluoride (CF₄) and oxygen. According to one embodiment, a flow of CF₄ is in the range of 30˜150 sccm, preferably in the range of 50˜90 sccm, while the flow of oxygen is in the range of 5˜40 sccm, preferably in the range of 10˜25 sccm.

The thickness of the high voltage gate dielectric layer 220 is approximately 200˜500 angstrom, and thus the amount etched in the dry etching step is merely hundreds of angstroms in thickness, approximately. To achieve etching uniformity, the pressure in the reaction chamber is raised to a highest degree according to the present embodiment, resulting in sufficient etching time and desirable etching uniformity. Said pressure in the reaction chamber is approximately 50˜300 mtorr, for example, preferably in the range of 100˜200 mtorr. After the dry etching step is performed, a half of or more than half of the thickness of the original high voltage gate dielectric layer 220 is removed. The remaining high voltage gate dielectric layer 220 having the thickness equal to or less than 100 angstrom is then removed by performing the subsequent wet etching step.

Despite the use of the polymer-less etching gas during the dry etching step, the residue of the polymer may still influence the subsequent wet etching step, such that the enchant efficiency of removing the high voltage gate dielectric layer 220 in the low voltage device region 204 is impaired. Hence, an ashing step for removing the residue of the polymer is performed after the dry etching step is carried out according to one embodiment. Preferably, oxygen and noble gases are used as reactive gases to implement an in-situ ashing step, instantly removing the possible residue of the polymer in the same reaction chamber according to one embodiment. However, in the embodiment, less etching amount of the passivation layer 230 is generated. Here, the noble gases may be nitrogen, argon, or any other inert gases. Argon is preferred.

Then, referring to FIG. 2C, the wet etching step is performed to remove the high voltage gate dielectric layer 220 in the low voltage device region 204. The etchant used in the wet etching step is, for example, hydrogen fluoride, such as diluted hydrogen fluoride (DHF) or buffer hydrogen fluoride (BHF). BHF containing ammonium fluoride (NH₄F) is preferred, and BHF containing surfactant is even more desirable.

Since the wet etching step is implemented after the dry etching step is performed, the thickness of the high voltage gate dielectric layer 220 removed by carrying out the wet etching step merely reaches approximately 100 angstrom. Corner portions of the isolation structures 210 are not etched in a great quantity, such that a boundary 215 between one of the isolation structures 210 and the surface of the substrate 200 is still located higher than the corner portion of the substrate 200.

Next, referring to FIG. 2D, the passivation layer 230 is removed, and the method of removing the same includes, for example, performing the dry etching step or the wet etching step. Suppose that the passivation layer 230 is the patterned photoresist layer, the method of removing the same includes performing a dry photoresist removing method or a wet photoresist removing method, for example. A plasma ashing method using oxygen or the wet photoresist removing method using reactive sulfuric acid and hydrogen peroxide is preferred.

Thereafter, a low voltage gate dielectric layer 240 is formed on the substrate 200 in the low voltage device region 204. The material of the low voltage gate dielectric layer 240 is, for example, silicon oxide, and the method of forming the low voltage gate dielectric layer 240 includes, for example, performing the thermal oxidation process. The boundary 215 between one of the isolation structures 210 and the surface of the substrate 200 is located higher than the corner portion of the substrate 200. Thereby, the thinning phenomenon caused by the divots at the corner portions of the isolation structures 210 is not generated on the low voltage gate dielectric layer 240, such that the low voltage gate dielectric layer 240 can be uniformly formed on the substrate 200, which is conducive to an enhancement of the reliability of the low voltage gate dielectric layer 240. Further, the electrical problems including charge-to-breakdown, voltage breakdown, threshold voltage shift, or the like can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a gate dielectric layer, comprising:
providing a substrate including a high voltage device region and a low voltage device region, a plurality of isolation structures being formed in the substrate and protruding from the substrate;
forming a high voltage gate dielectric layer on the substrate;
forming a passivation layer on the high voltage gate dielectric layer in the high voltage device region;
performing a dry etching step to remove a portion of the high voltage gate dielectric layer in the low voltage device region;
performing a wet etching step to remove the remaining high voltage gate dielectric layer in the low voltage device region;
removing the passivation layer; and
forming a low voltage gate dielectric layer on the substrate in the low voltage device region.

2. The method of claim 1, wherein a boundary between the isolation structure and a surface of the substrate is located higher than a corner portion of the substrate after the wet etching step is performed.

3. The method of claim 1, wherein the dry etching step comprises performing a reactive ion etching process.

4. The method of claim 1, wherein the dry etching step is a low power dry etching step.

5. The method of claim 4, wherein the power consumed in the low power dry etching step ranges from 50 to 200 watt.

6. The method of claim 1, wherein a polymer-less etching gas is used in the dry etching step.

7. The method of claim 6, wherein the etching gas comprises carbon tetrafluoride (CF₄) and oxygen.

8. The method of claim 7, wherein a flow of CF₄ ranges from 30 to 150 sccm while the flow of oxygen ranges from 5 to 40 sccm.

9. The method of claim 1, wherein a pressure in a reaction chamber ranges from 50 to 300 mtorr during the dry etching step.

10. The method of claim 1, wherein a thickness of the remaining high voltage gate dielectric layer in the low voltage device region is equal to or less than a half of the thickness of the original high voltage gate dielectric layer after the dry etching step is performed.

11. The method of claim 1, further comprising performing an ashing step between the dry and the wet etching steps.

12. The method of claim 11, wherein oxygen and noble gases are used as reactive gases in the ashing step.

13. The method of claim 1, wherein an etchant used in the wet etching step comprises hydrogen fluoride.

14. The method of claim 1, wherein the method of forming the low voltage gate dielectric layer comprises performing a thermal oxidation process.

15. The method of claim 1, wherein the passivation layer is a patterned photoresist layer.
